(19) United States
(12) Patent Application Publication
(10) Pub. No.: US 2025/0301754 A1
(43) Pub. Date: Sep. 25, 2025

(54) SEMICONDUCTOR DEVICE, SEMICONDUCTOR MEMORY DEVICE, AND METHOD OF MANUFACTURING SEMICONDUCTOR DEVICE

(71) Applicant: Kioxia Corporation, Tokyo (JP)

(72) Inventors: Tomoki HARADA, Yokkaichi Mie (JP); Yusuke MIKI, Yokkaichi Mie (JP); Kazuhiro KATONO, Mie Mie (JP); Yusuke MUTO, Yokkaichi Mie (JP); Jiro HATANO, Yokkaichi Mie (JP); Yurika SERIZAWA, Yokkaichi Mie (JP); Akifumi GAWASE, Kuwana Mie (JP)

(21) Appl. No.: 19/070,367

(22) Filed: Mar. 4, 2025

(30) Foreign Application Priority Data
Mar. 22, 2024 (JP) 2024-046608

(51) Int. Cl. H10D 64/62; H10D 30/01; H10D 30/63; H10D 62/17; H10D 62/80; H10D 64/27; H10D 84/01; H10D 84/80

(52) U.S. Cl. CPC H10D 64/62; H10D 30/025; H10D 30/63; H10D 62/235; H10D 62/875; H10D 64/514; H10D 84/0128; H10D 84/0149; H10D 84/813

(57) ABSTRACT

A semiconductor device includes: a first conductor layer; a second conductor layer; an oxide semiconductor layer provided between the first conductor layer and the second conductor layer; a gate electrode provided next to the oxide semiconductor layer; and a gate insulating film provided between the gate electrode and the oxide semiconductor layer. The oxide semiconductor layer includes at least one of indium, gallium, zinc, aluminum, tin, titanium, silicon, germanium, copper, arsenic, and tungsten and oxygen and includes a first end and a second end. The first conductor layer includes indium, tin, oxygen, and a first element that is at least one of nitrogen, sulfur, selenium, tellurium, hafnium, tantalum, tungsten, rhenium, osmium, iridium, bismuth, lanthanum, yttrium, zinc, cadmium, and mercury. The first end of the oxide semiconductor layer is in contact with the first conductor layer.

### CROSS-REFERENCE TO RELATED APPLICATION(S)

This application is based upon and claims the benefit of priority from Japanese Patent Application No. 2024-046608, filed Mar. 22, 2024, the entire contents of which are incorporated herein by reference.

### FIELD

Embodiments described herein relate generally to a semiconductor device, a semiconductor memory device, and a method of manufacturing a semiconductor device.

### BACKGROUND

A semiconductor element may include oxygen.

### BRIEF DESCRIPTION OF THE DRAWINGS

FIG. 1 is a circuit diagram illustrating a circuit configuration example of a memory cell array according to an embodiment.

FIG. 2 is a schematic cross-sectional view of a semiconductor memory device according to the present embodiment.

FIG. 3 is another schematic cross-sectional view of the semiconductor device according to the present embodiment.

FIG. 4 is a cross-sectional view of the semiconductor device according to the present embodiment taken along cutting-plane line IV-IV illustrated in FIG. 3.

FIGS. 5-16 are cross-sectional views illustrating a process of manufacturing the semiconductor device according to the present embodiment.

FIG. 17 is a schematic cross-sectional view of the semiconductor device according to the present embodiment.

FIG. 18 is a diagram illustrating an example of a distribution of ions in IGZO when IGZO and ITO are not in contact with each other.

FIG. 19 is a diagram illustrating polarization in IGZO when IGZO and ITO are in contact with each other.

FIG. 20 is a diagram illustrating an example of a distribution of indium and oxygen in ITO.

FIG. 21 is a diagram illustrating an example of a distribution of nitrogen, indium, and oxygen in a lower electrode of the present embodiment.

FIG. 22 is a diagram illustrating an example of a concentration distribution of nitrogen in the lower electrode of the present embodiment.

FIG. 23 is a diagram illustrating an example of a concentration distribution of oxygen in the lower electrode of the present embodiment.

FIGS. 24-26 are cross-sectional views illustrating a process of manufacturing a semiconductor device according to a first modification example of the present embodiment.

FIG. 27 is a cross-sectional view illustrating cutting-plane line XXVII-XXVII illustrated in FIG. 26.

FIGS. 28-30 are additional cross-sectional views illustrating the manufacturing process of the semiconductor device according to the first modification example of the present embodiment.

FIGS. 31-34 are cross-sectional views illustrating a process of manufacturing a semiconductor device according to a second modification example of the present embodiment.

### DETAILED DESCRIPTION

A technique of reducing a contact resistance between a semiconductor layer including oxygen and a conductor layer is required.

Embodiments provide a semiconductor device, a semiconductor memory device, and a method of manufacturing a semiconductor device in which a contact resistance between a semiconductor layer including oxygen and a conductor layer can be reduced.

In general, according to one embodiment, a semiconductor device includes: a first conductor layer; a second conductor layer; an oxide semiconductor layer provided between the first conductor layer and the second conductor layer; a gate electrode provided next to the oxide semiconductor layer; and a gate insulating film provided between the gate electrode and the oxide semiconductor layer. The oxide semiconductor layer includes at least one of indium, gallium, zinc, aluminum, tin, titanium, silicon, germanium, copper, arsenic, and tungsten and oxygen and includes a first end and a second end. The first conductor layer includes indium, tin, oxygen, and a first element that is at least one of nitrogen, sulfur, selenium, tellurium, hafnium, tantalum, tungsten, rhenium, osmium, iridium, bismuth, lanthanum, yttrium, zinc, cadmium, and mercury. The first end of the oxide semiconductor layer is in contact with the first conductor layer.

A semiconductor memory device according to another embodiment includes: the above-described semiconductor device; and a capacitor electrically connected to the first conductor layer, wherein the capacitor includes a first capacitor electrode, a second capacitor electrode, and a dielectric film provided between the first capacitor electrode and the second capacitor electrode.

A method of manufacturing a semiconductor device according to still another embodiment includes: forming a first oxide conductive film on a substrate, the oxide conductive film including indium, tin, oxygen, and at least one of nitrogen, sulfur, selenium, tellurium, hafnium, tantalum, tungsten, rhenium, osmium, iridium, bismuth, lanthanum, yttrium, zinc, cadmium, and mercury; forming a structure that includes a first insulating film, a second conductive film, and a second insulating film stacked on the first oxide conductive film; forming a hole portion in the structure such that a surface of the first oxide conductive film formed on the substrate is exposed; forming a third insulating film to cover the inside of the hole portion; removing the third insulating film formed on the first oxide conductive film; and forming an oxide semiconductor film in the hole portion such that the oxide semiconductor film is in contact with the first oxide conductive film.

Hereinafter, an embodiment will be described with reference to the accompanying drawings. For easy understanding of the description, in the drawings, the same components are represented by the same reference numerals, and the description thereof will not be repeated.

A configuration of a semiconductor memory device according to the embodiment will be described. Each of the drawings illustrates an X-axis, a Y-axis, and a Z-axis. The X-axis, the Y-axis, and the Z-axis form three-dimensional Cartesian coordinates of the right-handed system. Hereinafter, an arrow direction of the X-axis will also be referred to as an X-axis+direction, and a direction opposite to the arrow will also be referred to as an X-axis-direction. The same applies to the other axes. The Z-axis+direction and the Z-axis-direction will also be referred to as “upper” and “lower”, respectively. In addition, a plane perpendicular to the X-axis, the Y-axis, or the Z-axis will also be referred to as a YZ plane, a ZX plane, or an XY plane. In addition, the Z-axis direction will also be referred to as “up-down direction”. “Upper”, “lower”, and “up-down direction” are merely terms representing a relative position relationship in the drawings, and are not terms that define directions with respect to the vertical direction.

In addition, unless otherwise specified, the dimensions or the like of components in each of the drawings may be different from the actual ones for easy understanding of the description.

In the present specification, the meaning of “connection” includes not only physical connection but also electrical connection and, unless otherwise specified, includes not only direct connection but also indirect connection.

In the present specification, the meaning of “being formed on or above” includes not only being formed in contact with a substance but also, unless otherwise specified, being formed on or above a substance with another substance interposed therebetween. The same applies to, for example, “being formed under or below”.

A semiconductor memory device 101 according to the present embodiment is an oxide semiconductor random access memory (OS-RAM) and includes a memory cell array.

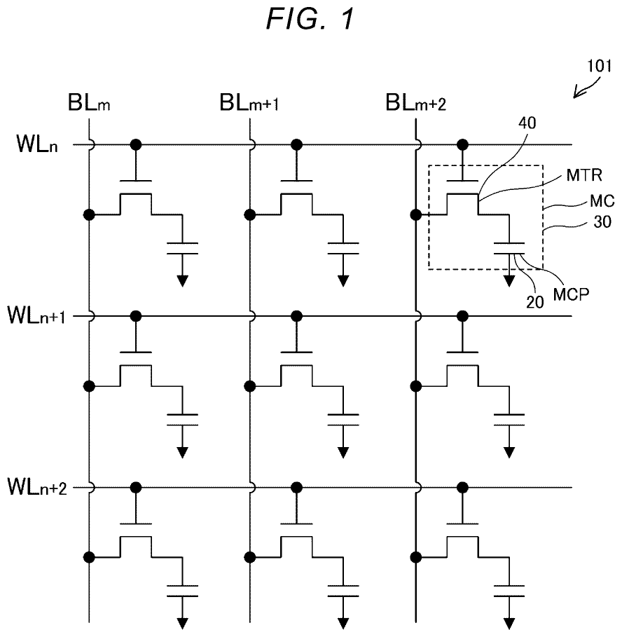

As illustrated in FIG. 1, the memory cell array includes a plurality of memory cells MC, a plurality of word lines WL, and a plurality of bit lines BL.

FIG. 1 illustrates, as an example of the plurality of word lines WL, a word line WLₙ, a word line WLₙ₊₁, and a word line WLₙ₊₂ (here, n represents a positive integer). In addition, FIG. 1 illustrates, as an example of the bit lines BL, a bit line BLₘ, a bit line BLₘ₊₁, and a bit line BLₘ₊₂ (here, m represents a positive integer). The number of the plurality of memory cells MC is not limited to the number illustrated in FIG. 1.

For example, the plurality of memory cells MC are arranged in a matrix configuration to form a memory cell array. The memory cell MC includes a memory transistor MTR that is a field effect transistor (FET) and a memory capacitor MCP.

A series of memory cells MC provided in the row direction are connected to a word line WL (for example, the word line WLₙ) corresponding to a row (for example, the n-th row) belonging to the series of memory cells MC. A series of memory cells MC provided in the column direction are connected to a bit line BL (for example, the bit line BLₘ₊₂) corresponding to a column (for example, the m+2-th column) belonging to the series of memory cells MC.

Specifically, a gate of the memory transistor MTR in the memory cell MC is connected to a word line WL corresponding to a row belonging to the memory cell MC. One of a source or a drain of the memory transistor MTR is connected to a bit line BL corresponding to a column belonging to the memory cell MC.

One electrode of the memory capacitor MCP in the memory cell MC is connected to the remaining one of the source or the drain of the memory transistor MTR in the memory cell MC. The remaining electrode of the memory capacitor MCP is connected to a power supply line (not illustrated) for supplying a specific voltage.

The memory cell MC is configured to store data by storage of charge in the memory capacitor MCP using a current flowing through the corresponding bit line BL due to switching of the memory transistor MTR based on the voltage of the corresponding word line WL.

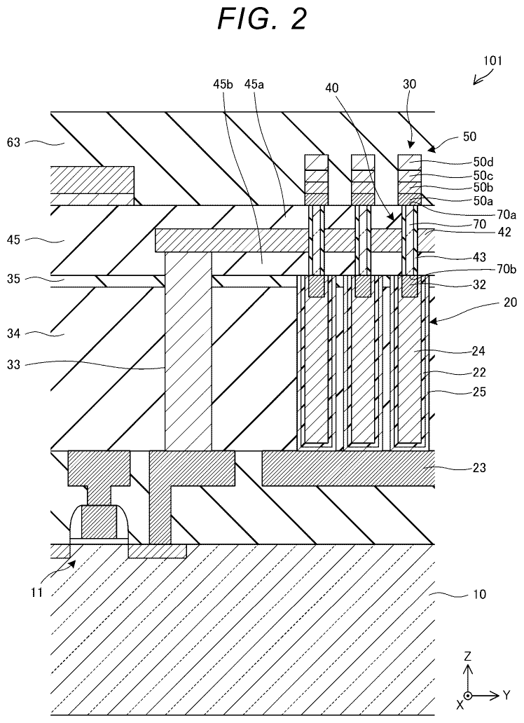

As illustrated in FIG. 2, the semiconductor memory device 101 includes a semiconductor substrate 10, a circuit 11 (an example of “semiconductor circuit”), a capacitor 20, a semiconductor device 30, a conductor 33, and insulating layers 34, 35, and 63.

The capacitor 20 includes an insulating film 22 (an example of “dielectric film”), a capacitor electrode 24 (an example of “first capacitor electrode”), and a capacitor electrode 25 (an example of “second capacitor electrode”).

The semiconductor device 30 includes a field effect transistor 40, an upper electrode 50 provided above the field effect transistor 40, and a lower electrode 32 (an example of “first conductor layer” and “first oxide conductive film”) provided below the field effect transistor 40.

The field effect transistor 40 includes an oxide semiconductor layer 70 (an example of “oxide semiconductor film”), a gate insulating film 43 (an example of “third insulating film”), a conductive layer 42 (an example of “gate electrode” and “second conductive film”), and an insulating layer 45. The insulating layer 45 includes an insulating film 45a (an example of “second insulating film” and an insulating film 45b (an example of “first insulating film”).

The oxide semiconductor layer 70 is formed in the insulating layer 45 and includes an upper end 70a (an example of “second end”) and a lower end 70b (an example of “first end”). The oxide semiconductor layer 70 is a columnar body extending in the Z-axis+direction from the lower end 70b toward the upper end 70a. The oxide semiconductor layer 70 forms a channel of the field effect transistor 40, and the oxide semiconductor layer 70 has an amorphous structure.

The conductive layer 42 faces the oxide semiconductor layer 70 through the gate insulating film 43. Specifically, the conductive layer 42 functions as a gate electrode of the field effect transistor 40, and surrounds the oxide semiconductor layer 70 through the gate insulating film 43, which surrounds the oxide semiconductor layer 70 between the upper end 70a and the lower end 70b of the oxide semiconductor layer 70. The conductive layer 42 includes, for example, tungsten (W).

The gate insulating film 43 includes, for example, a silicon nitride film (Si₃N₄) including silicon and nitrogen.

The upper electrode 50 is formed in the Z-axis+direction with respect to the oxide semiconductor layer 70, and is connected to the upper end 70a of the oxide semiconductor layer 70. The upper electrode 50 includes a metal oxide film 50a (an example of “second conductor layer” and “second oxide conductive film”), a barrier metal layer 50b, a metal film 50c, and a metal film 50d.

The metal film 50d includes, for example, tungsten. The metal film 50c is provided between the metal film 50d and the barrier metal layer 50b, and is formed of, for example, titanium nitride (TiN).

The metal oxide film 50a is in contact with the upper end 70a of the oxide semiconductor layer 70, and is provided between the metal film 50c and the upper end 70a of the oxide semiconductor layer 70. The metal oxide film 50a corresponds to an electrode of the memory transistor MTR (refer to FIG. 1) that is electrically connected to the bit line BL (refer to FIG. 1).

The barrier metal layer 50b is provided between the metal film 50c and the metal oxide film 50a, and is formed of, for example, titanium oxide (TiO).

The lower electrode 32 is in contact with the lower end 70b of the oxide semiconductor layer 70. The lower electrode 32 corresponds to an electrode of the memory transistor MTR (refer to FIG. 1) that is electrically connected to the memory cell MC (refer to FIG. 1).

The circuit 11 is part of a peripheral circuit such as a decoder for selecting a predetermined memory cell MC, a sense amplifier connected to the bit line BL, or a register formed of a SRAM in the plurality of memory cells MC of the semiconductor memory device 101, that is, the capacitor 20 and the field effect transistor 40. The circuit 11 may include a CMOS circuit including field effect transistors of a P-channel field effect transistor (Pch-FET) and an N-channel field effect transistor (Nch-FET) formed in a CMOS process.

The field effect transistor of the circuit 11 can be formed, for example, using the semiconductor substrate 10 such as a single-crystal silicon substrate. Each of the Pch-FET and the Nch-FET is a so-called lateral field effect transistor that includes a channel region, a source region, and a drain region in the semiconductor substrate 10 and includes a channel for causing carriers to flow in the X-axis direction or the Y-axis direction substantially parallel to a surface of the semiconductor substrate 10 in a region adjacent to the surface of the semiconductor substrate 10. The semiconductor substrate 10 may include a P-type or N-type conductivity type. For convenience of description, FIG. 2 illustrates an example of the field effect transistor of the circuit 11.

The capacitor 20 is the memory capacitor MCP in the memory cell MC (refer to FIG. 1). FIG. 2 illustrates three capacitors 20, but the number of the capacitors 20 is not limited to three.

In the present embodiment, the capacitor 20 is provided above the semiconductor substrate 10. The capacitor electrode 24 in the capacitor 20 is connected to the lower electrode 32. The capacitor electrode 25 faces the capacitor electrode 24. The insulating film 22 is provided between the capacitor electrode 24 and the capacitor electrode 25.

The capacitor 20 is a three-dimensional capacitor. As the capacitor according to the present embodiment, another capacitor having a configuration capable of storing charge may be adopted.

The lower electrode 32 is embedded in an upper end of the capacitor electrode 24. The capacitor electrode 24 has a columnar shape extending downward from the upper end. The insulating film 22 covers the capacitor electrode 24. The capacitor electrode 25 covers the insulating film 22, and includes a lower end abutting against an upper end surface of a conductor 23.

The capacitor electrode 24 may include a material such as SiGe including silicon and germanium or titanium nitride including nitrogen and titanium. The capacitor electrode 24 may have a two-layer structure, for example, may include TiN and SiGe.

The insulating film 22 may include a material such as ZrAlO including zirconium, aluminum, and oxygen. The conductor 23 and the capacitor electrode 25 may include a material such as tungsten or titanium nitride.

The conductor 33 includes a wiring through which the circuit 11 and the semiconductor device 30 are electrically connected. The conductor 33 may include a via wiring, for example, may include a via wiring that extends in the Z-axis direction as illustrated in FIG. 2 and through which the conductive layer 42 functioning as the word line WL and the circuit 11 provided on the semiconductor substrate 10 are connected. The conductor 33 includes, for example, copper.

The insulating layer 34 is provided between the plurality of capacitors 20. The insulating layer 34 is, for example, a silicon oxide film including silicon and oxygen.

The insulating layer 35 is provided above the insulating layer 34. The insulating layer 35 is, for example, a silicon nitride film including silicon and nitrogen.

The semiconductor device 30 is provided above the capacitor 20. The field effect transistor 40 in the semiconductor device 30 corresponds to the memory transistor MTR of the memory cell MC (refer to FIG. 1).

In the semiconductor device 30, the field effect transistor 40 is provided above the lower electrode 32. Specifically, the oxide semiconductor layer 70 of the field effect transistor 40 is positioned in a direction away from the semiconductor substrate 10 with respect to the lower electrode 32, that is, above the semiconductor substrate 10.

The upper electrode 50 is positioned in a direction away from the semiconductor substrate 10 with respect to the oxide semiconductor layer 70, that is, above the semiconductor substrate 10. With the above-described configuration, the field effect transistor 40 is a so-called vertical transistor that includes a channel extending in the Z-axis direction (up-down direction) substantially perpendicular to the surface of the semiconductor substrate 10. In addition, the oxide semiconductor layer 70 is a semiconductor where an oxygen defect functions as a donor.

The oxide semiconductor layer 70 includes at least one of indium (In), gallium (Ga), zinc (Zn), aluminum (Al), tin (Sn), titanium (Ti), silicon (Si), germanium (Ge), copper (Cu), arsenic (As), and tungsten (W) and oxygen (O).

In the present embodiment, the oxide semiconductor layer 70 includes, for example, indium, zinc, and gallium as metal elements. Specifically, the oxide semiconductor layer 70 is an oxide of indium, gallium, and zinc, that is, IGZO (InGaZnO). The oxide semiconductor layer 70 may be another kind of an oxide semiconductor.

The lower electrode 32 includes indium (In), tin (Sn), oxygen (O), and a first addition element (an example of “first element”) that is at least one of nitrogen (N), sulfur(S), selenium (Se), tellurium (Te), hafnium (Hf), tantalum (Ta), tungsten (W), rhenium (Re), osmium (Os), iridium (Ir), bismuth (Bi), lanthanum (La), yttrium (Y), zinc (Zn), cadmium (Cd), and mercury (Hg).

The metal oxide film 50a includes indium, tin, oxygen, and a second addition element (an example of “second element”) that is at least one of nitrogen, sulfur, selenium, tellurium, hafnium, tantalum, tungsten, rhenium, osmium, iridium, bismuth, lanthanum, yttrium, zinc, cadmium, and mercury.

A concentration of the first addition element in the lower electrode 32 is 3% or higher. A concentration of the second addition element in the metal oxide film 50a is 3% or higher.

In the present embodiment, each of the lower electrode 32 and the metal oxide film 50a includes nitrogen, indium, tin, and oxygen. A concentration of nitrogen in each of the lower electrode 32 and the metal oxide film 50a is 3% or higher.

The lower electrode 32 is formed before forming the oxide semiconductor layer 70. The metal oxide film 50a is formed after forming the oxide semiconductor layer 70.

A concentration of each of the elements in each of the members such as the lower electrode 32, the metal oxide film 50a, and the oxide semiconductor layer 70 of semiconductor device 30 can be measured, for example, transmission electron microscopy-electron energy loss spectroscopy (TEMEELS) or energy dispersive X-ray spectroscopy (EDX).

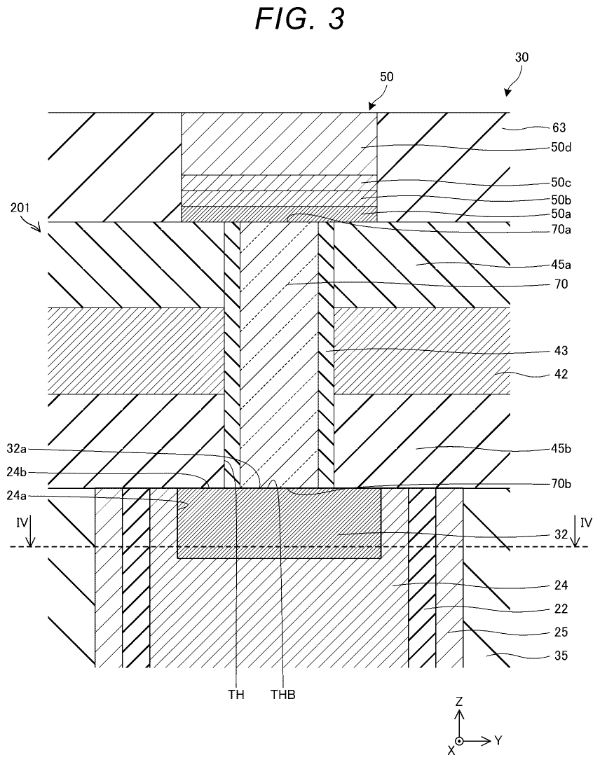

As illustrated in FIG. 3, in the capacitor electrode 24, a recess portion 24a where an opening 24b is formed in an upper portion is formed. The entirety of the lower electrode 32 is embedded in the recess portion 24a. Alternatively, a part of the lower electrode 32 may be configured to be embedded in the recess portion 24a.

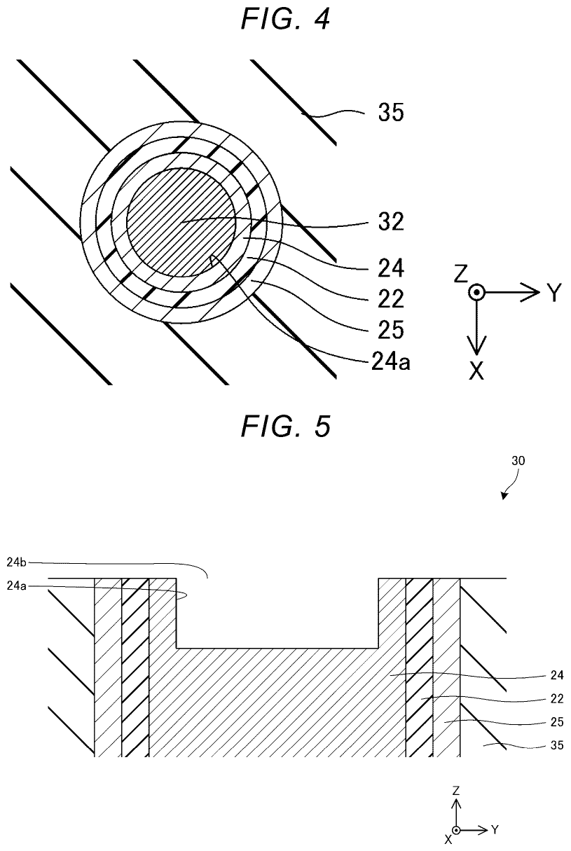

FIG. 4 is a cross-sectional view taken along cutting-plane line IV-IV illustrated in FIG. 3. As illustrated in FIG. 4, in a cross-section (an example of “first cross-section) substantially parallel to an XY plane perpendicular to the Z-axis direction (an example of “first direction”), the capacitor electrode 24 surrounds the lower electrode 32 and is in contact with the lower electrode 32. In the cross-section, the insulating film 22 surrounds the capacitor electrode 24 and is in contact with the capacitor electrode 24. In the cross-section, the capacitor electrode 25 surrounds the insulating film 22 and is in contact with the insulating film 22.

### [Method of Manufacturing Semiconductor Device]

Hereinafter, a method of manufacturing the semiconductor device 30 will be described as an example of a method of manufacturing a semiconductor device according to a first embodiment.

First, as illustrated in FIG. 5, after forming the insulating film 22, the capacitor electrodes 24 and 25, and the insulating layer 35, the recess portion 24a is formed above the capacitor electrode 24. The opening 24b is formed in an upper portion of the recess portion 24a.

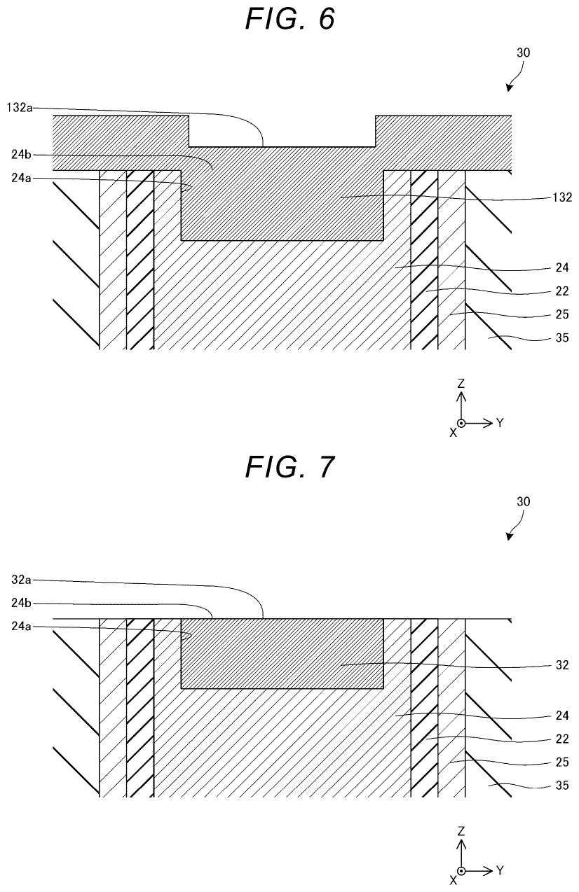

Next, as illustrated in FIG. 6, a first oxide conductive film 132 including the first addition element, indium, tin, and oxygen is formed above the semiconductor substrate 10. In the present embodiment, the first oxide conductive film 132 includes nitrogen, indium, tin, and oxygen. At this time, the recess portion 24a in the capacitor electrode 24 is embedded with the first oxide conductive film 132. The details of a method of forming the first oxide conductive film 132 will be described below.

Next, as illustrated in FIG. 7, a part of the first oxide conductive film 132 is removed using a chemical mechanical polishing method. An upper surface of the insulating layer 35 and a position of a surface 132a (hereinafter, also referred to as an upper surface 32a) of the first oxide conductive film 132 in the Z direction are aligned, and the upper surface 32a is exposed from the opening 24b. The first oxide conductive film 132 that is embedded in the recess portion 24a formed in the capacitor electrode 24 is the lower electrode 32.

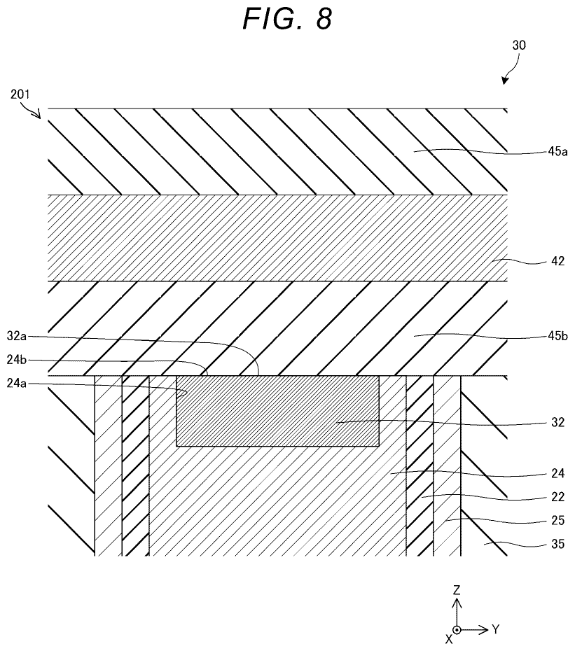

Next, as illustrated in FIG. 8, a structure 201 where the insulating film 45b (an example of “first insulating film”), the conductive layer 42 (an example of “second conductive film”), and the insulating film 45a (an example of “second insulating film”) are stacked on the upper surface 32a of the first oxide conductive film 132, is formed. In the structure 201, the insulating film 45b, the conductive layer 42, and the insulating film 45a are stacked in order from the lower side toward the upper side. The insulating film 45b, the conductive layer 42, and the insulating film 45a extend substantially parallel to the XY plane.

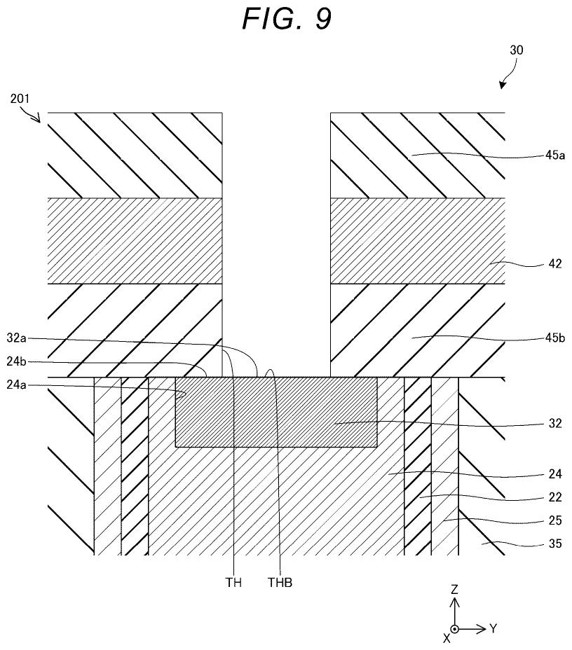

Next, as illustrated in FIG. 9, a transistor hole TH (an example of “hole portion”) is formed in the structure 201 and then cleaned such that the upper surface 32a (an example of “surface”) of the lower electrode 32 is exposed. The transistor hole TH extends substantially parallel to the Z-axis, and penetrates the insulating film 45a, the conductive layer 42, and the insulating film 45b. In a bottom portion THB of the transistor hole TH, the upper surface 32a of the lower electrode 32 is exposed.

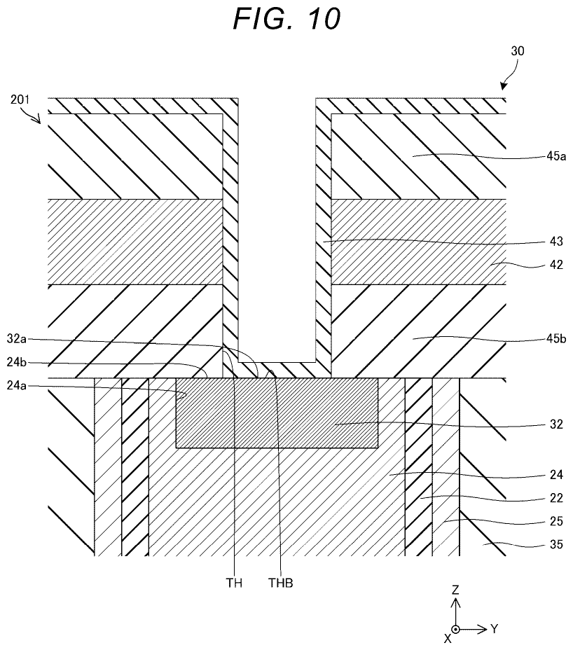

Next, as illustrated in FIG. 10, the gate insulating film 43 (an example of “third insulating film”) covers an upper surface of the insulating film 45a and the inside of the transistor hole TH.

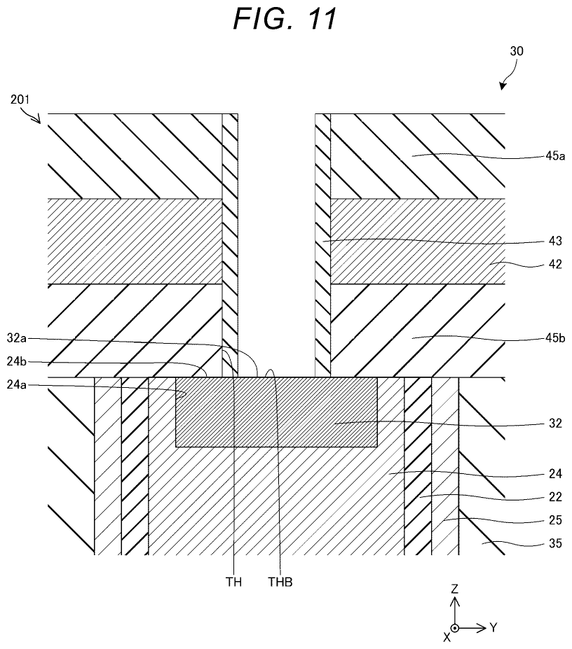

Next, as illustrated in FIG. 11, a part of the gate insulating film 43 is etched by reactive ion etching. As a result, the upper surface 32a of the lower electrode 32 is exposed in the bottom portion THB of the transistor hole TH.

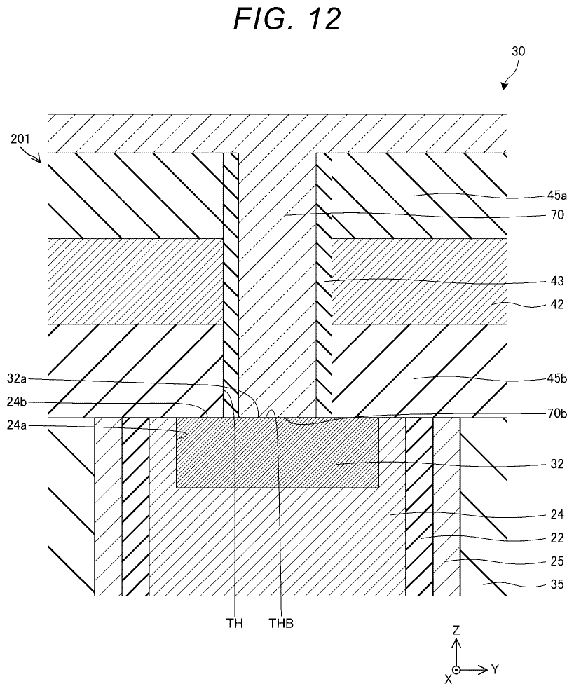

Next, as illustrated in FIG. 12, the oxide semiconductor layer 70 is formed on the upper surface of the insulating film 45a and the transistor hole TH. The oxide semiconductor layer 70 is in contact with the upper surface 32a of the lower electrode 32 exposed in the bottom portion THB of the transistor hole TH. As a result, the transistor hole TH is embedded with the oxide semiconductor layer 70.

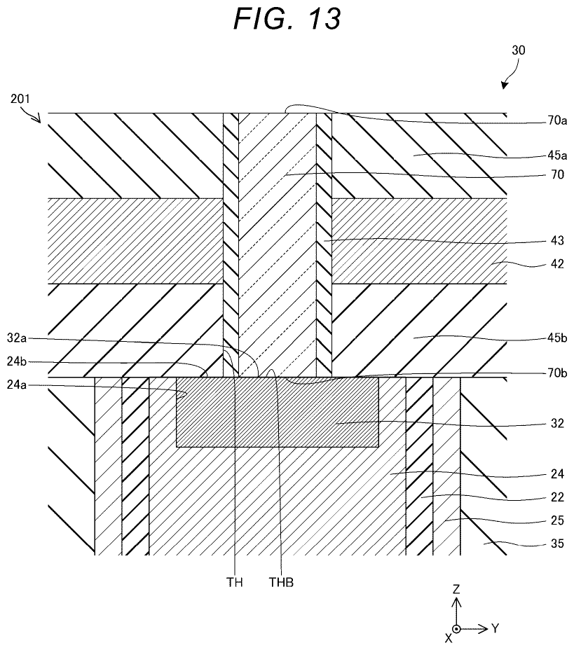

Next, as illustrated in FIG. 13, a part of the oxide semiconductor layer 70 is removed, and the upper surface of the insulating film 45a is exposed. At this time, a surface of the upper end 70a of the oxide semiconductor layer 70 is aligned with a position of the upper surface of the insulating film 45a in the Z direction.

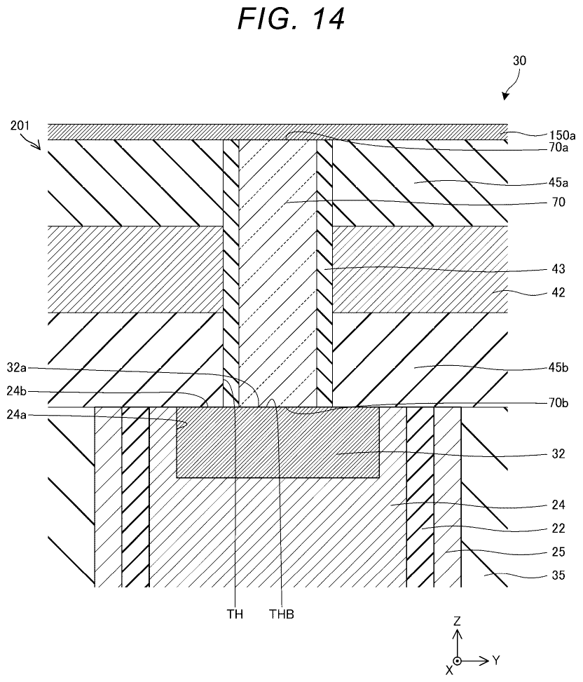

Next, as illustrated in FIG. 14, a second oxide conductive film 150a including the second addition element, indium, tin, and oxygen is formed on the oxide semiconductor layer 70 and the insulating film 45a. In the present embodiment, the second oxide conductive film 150a includes nitrogen, indium, tin, and oxygen. The second oxide conductive film 150a extends substantially parallel to the XY plane.

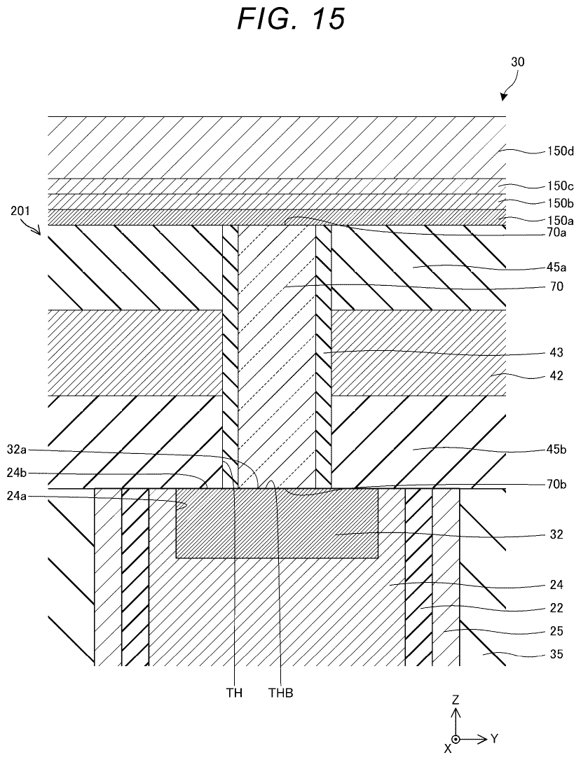

Next, as illustrated in FIG. 15, a barrier metal film 150b and metal films 150c and 150d are formed on the second oxide conductive film 150a from the lower side toward the upper side. The barrier metal film 150b and the metal films 150c and 150d extend substantially parallel to the XY plane.

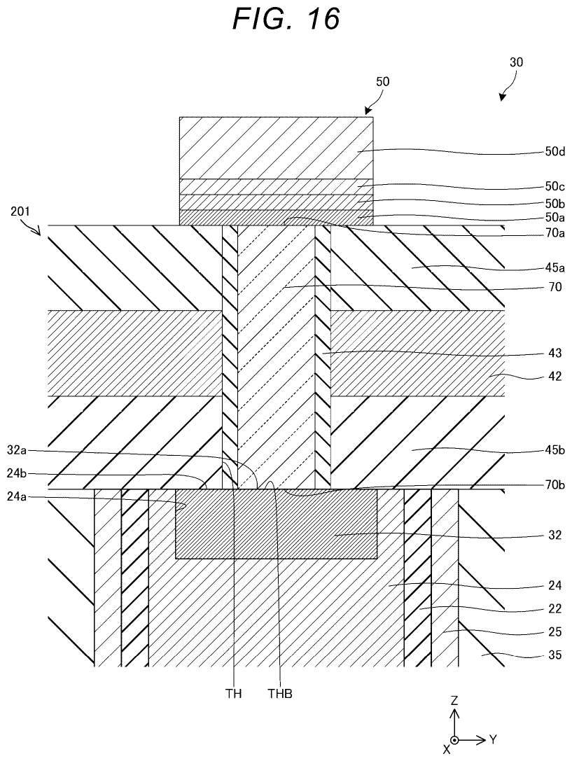

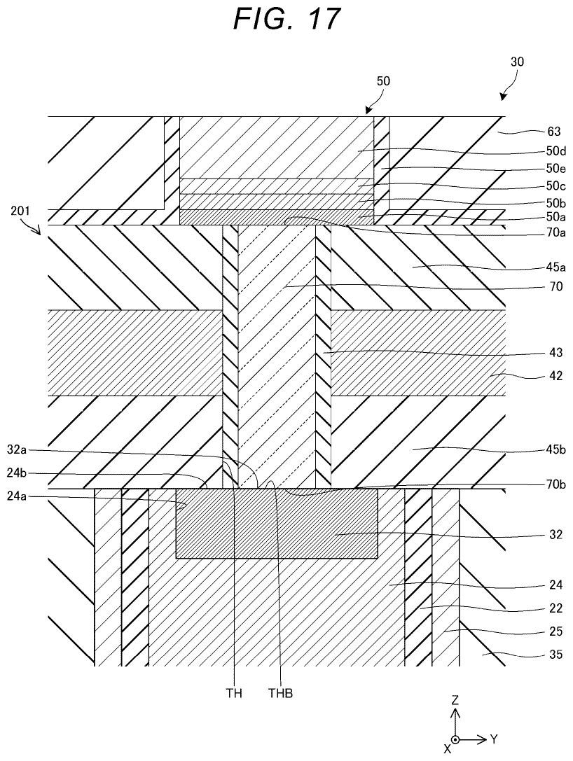

Next, as illustrated in FIG. 16, the upper electrode 50 is formed by etching the metal film 150d, the metal film 150c, the barrier metal film 150b, and the second oxide conductive film 150a. The upper electrode 50 functions as a landing pad. The upper electrode 50 includes the metal oxide film 50a, the barrier metal layer 50b, the metal film 50c, and the metal film 50d.

Next, as illustrated in FIG. 3, an insulating layer 63 covers the upper electrode 50. The insulating layer 63 includes, for example, an oxide of silicon. A part of the insulating layer 63 is polished by chemical mechanical polishing such that the upper electrode 50 is exposed.

As illustrated in FIG. 17, the insulating layer 63 may be configured to be formed after forming an LP liner film 50e for protecting a part or all of side walls of the upper electrode 50. Specifically, the LP liner film 50e includes, for example, an oxide of silicon. The LP liner film 50e covers the upper electrode 50. Next, the insulating layer 63 that is embedded in a gap formed by the LP liner film 50e is formed above the LP liner film 50e. An upper surface of the insulating layer 63 is polished by chemical mechanical polishing such that the upper electrode 50 is exposed.

### [Formation of Lower Electrode 32]

As illustrated in FIG. 6, a case where the first oxide conductive film 132 is formed by chemical sputtering will be described. The first oxide conductive film 132 is formed by depositing an oxide conductor including indium, tin, and oxygen using a sputtering method in a state where gas including nitrogen and sulfur is introduced when the first oxide conductive film 132 is formed above the semiconductor substrate 10. The gas may include at least one of selenium, tellurium, hafnium, tantalum, tungsten, rhenium, osmium, iridium, bismuth, lanthanum, yttrium, zinc, cadmium, and mercury.

In addition, in order to form the first oxide conductive film 132, the following method may be used in addition to chemical sputtering. Here, a case where the first oxide conductive film 132 is formed by co-sputtering will be described. The first oxide conductive film 132 may be formed with a sputtering method using a target including at least one of nitrogen, sulfur, selenium, tellurium, hafnium, tantalum, tungsten, rhenium, osmium, iridium, bismuth, lanthanum, yttrium, zinc, cadmium, and mercury and a target including indium, tin, and oxygen.

In addition, a case where the first oxide conductive film 132 is formed using a single target will be described. The first oxide conductive film 132 may be formed with a sputtering method using a target including indium, tin, oxygen, and at least one of nitrogen, sulfur, selenium, tellurium, hafnium, tantalum, tungsten, rhenium, osmium, iridium, bismuth, lanthanum, yttrium, zinc, cadmium, and mercury.

In addition, the first oxide conductive film 132 may be formed by forming a first film including indium, tin, and oxygen on the substrate and exposing the first film to gas including at least one of nitrogen, sulfur, selenium, tellurium, hafnium, tantalum, tungsten, rhenium, osmium, iridium, bismuth, lanthanum, yttrium, zinc, cadmium, and mercury.

In addition, the first oxide conductive film 132 may be formed by forming a first film including indium, tin, and oxygen and causing at least one of nitrogen, sulfur, selenium, tellurium, hafnium, tantalum, tungsten, rhenium, osmium, iridium, bismuth, lanthanum, yttrium, zinc, cadmium, and mercury that is ionized to collide with the first film using an electrical field.

### [Problem 1]

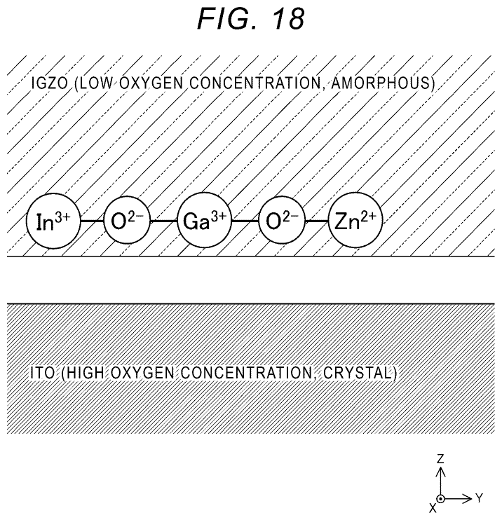

FIG. 18 is a diagram illustrating an example of a distribution of ions in IGZO when IGZO and ITO are not in contact with each other. As illustrated in FIG. 18, both of IGZO and ITO are oxides and are a semiconductor and a conductor, respectively. IGZO and ITO are, for example, an amorphous substance and crystal, respectively. An oxygen concentration in IGZO is lower than an oxygen concentration in ITO.

In a state where IGZO and ITO are not in contact with each other, deviation of a distribution of cations (indium ions, gallium ions, and zinc ions) and anions (oxygen ions) in IGZO is not large.

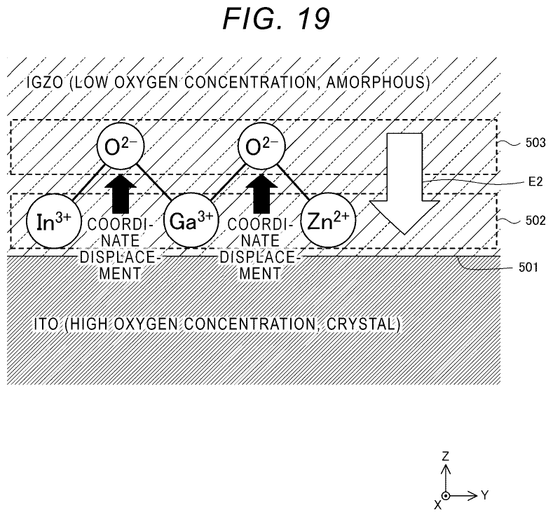

FIG. 19 is a diagram illustrating polarization in IGZO when IGZO and ITO are in contact with each other. As illustrated in FIG. 19, an oxygen concentration in ITO is higher than an oxygen concentration in IGZO. Therefore, due to this difference in concentration, the oxygen ions in IGZO may be displaced in a direction away from an interface 501 between ITO and IGZO.

Therefore, an anion layer 503 that has a high concentration of oxygen ions and a cation layer 502 that is positioned closer to the interface 501 than the anion layer 503 and has higher concentrations of indium ions, gallium ions, and zinc ions are formed.

In order to negatively charge the anion layer 503 as compared to the cation layer 502, a dipole where the anion layer 503 and the cation layer 502 are a negative electrode and a positive electrode, respectively is formed. Due to this dipole, an electrical field E2 from the anion layer 503 toward the cation layer 502 is generated. That is, a potential lobe is formed across the anion layer 503 to the interface 501. Therefore, a contact resistance between IGZO and ITO increases.

[Effect of Present Embodiment with Respect to Problem 1]

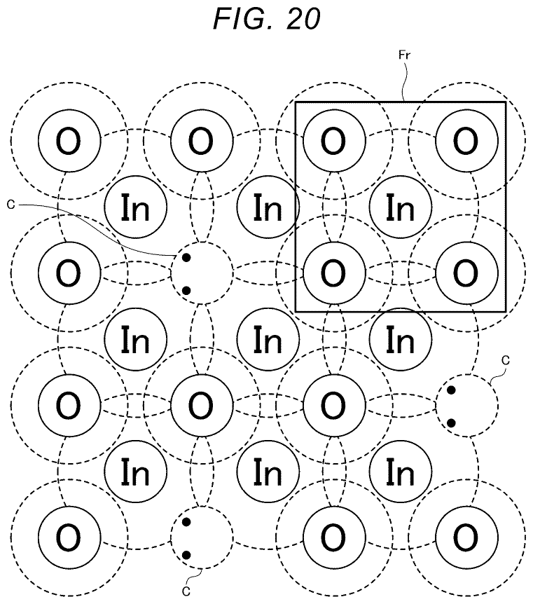

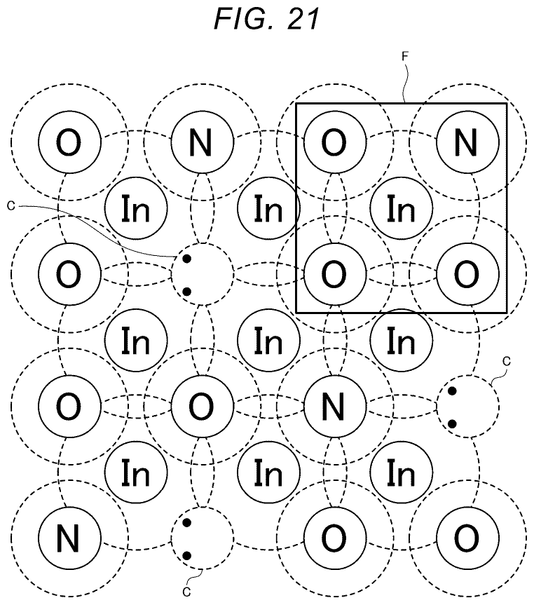

FIG. 20 is a diagram illustrating an example of a distribution of indium and oxygen in ITO. FIG. 21 is a diagram illustrating an example of a distribution of nitrogen, indium, and oxygen in the lower electrode 32 of the present embodiment. As illustrated in FIGS. 20 and 21, ITO and the lower electrode 32 include carriers C at positions where oxygen ions are deficient.

Since the lower electrode 32 includes nitrogen, a part of oxygen is substituted with nitrogen. Specifically, in a region Fr illustrated in FIG. 20, four oxygen atoms and one indium atom are present. In a region F illustrated in FIG. 21, one of four oxygen atoms is substituted with one nitrogen atom such that three oxygen atoms, one indium atom, and one nitrogen atom are present.

This way, the oxygen concentration in the lower electrode 32 can be reduced. Therefore, a difference between the oxygen concentration in the oxide semiconductor layer 70 and the oxygen concentration in the lower electrode 32 can be reduced. As a result, the displacement of the oxygen ions in the oxide semiconductor layer 70 can be reduced. Therefore, the size of the electrical field E2 can be reduced, and a contact resistance between the oxide semiconductor layer 70 and the lower electrode 32 can be reduced.

### [Problem 2]

For example, in a case where the recess portion 24a in the capacitor electrode 24 is embedded with an oxide conductive film by physical vapor deposition (PVD) (refer to FIG. 6), when ITO as the oxide conductive film is embedded, the opening 24b may be blocked with ITO before embedding the recess portion 24a with ITO. At this time, a cavity is formed in the recess portion 24a.

[Effect of Present Embodiment with Respect to Problem 2]

In the present embodiment, the first oxide conductive film 132 includes nitrogen, indium, tin, and oxygen, and is likely to be cut off as compared to ITO. Therefore, even when the first oxide conductive film 132 is formed in the opening 24b, the first oxide conductive film 132 is cut off by gas used in PVD. As a result, the blocking of the opening 24b is prevented. Therefore, the possibility of formation of a cavity in the recess portion 24a can be reduced.

### [Effect of First Addition Element]

In the present embodiment, the configuration where the first oxide conductive film 132 includes nitrogen, indium, tin, and oxygen is described. However, the present embodiment is not limited to this configuration. The first oxide conductive film 132 may include at least one of sulfur, selenium, and tellurium instead of nitrogen or in addition to nitrogen. With this configuration, the oxygen atom in the first oxide conductive film 132 can be easily substituted with sulfur, selenium, or tellurium belonging to the same group as oxygen.

In addition, the first oxide conductive film 132 may include at least one of hafnium, tantalum, tungsten, rhenium, osmium, iridium, bismuth, and lanthanum instead of nitrogen or in addition to nitrogen. Since ions of hafnium, tantalum, tungsten, rhenium, osmium, iridium, bismuth, and lanthanum have a large ionic radius, the number of oxygen atoms per unit volume can be reduced. That is, the oxygen concentration in the lower electrode 32 can be reduced. Therefore, a difference between the oxygen concentration in the oxide semiconductor layer 70 and the oxygen concentration in the lower electrode 32 can be reduced, and a contact resistance between the oxide semiconductor layer 70 and the lower electrode 32 can be reduced.

In addition, the first oxide conductive film 132 may include at least one of yttrium, zinc, cadmium, and mercury instead of nitrogen or in addition to nitrogen. Since ions of yttrium, zinc, cadmium, and mercury have a small valence, the number of oxygen atoms per unit volume can be reduced. That is, the oxygen concentration in the lower electrode 32 can be reduced. Therefore, a difference between the oxygen concentration in the oxide semiconductor layer 70 and the oxygen concentration in the lower electrode 32 can be reduced, and a contact resistance between the oxide semiconductor layer 70 and the lower electrode 32 can be reduced.

### [Concentration Distribution 1 of First Addition Element in Lower Electrode 32]

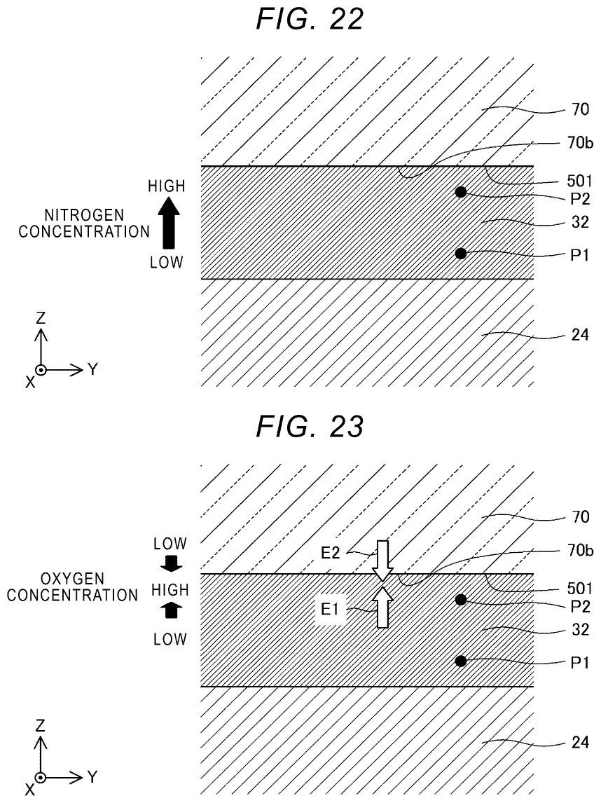

FIG. 22 is a diagram illustrating an example of a concentration distribution of nitrogen in the lower electrode of the present embodiment. As illustrated in FIG. 22, a concentration of the first addition element at a position P1 (an example of “first position”) in the lower electrode 32 is lower than a concentration of the first addition element at a position P2 (an example of “second position”) closer to the oxide semiconductor layer 70 than the position P1. In the present embodiment, a concentration of nitrogen at the position P1 is lower than a concentration of nitrogen at the position P2.

For example, when nitrogen is added to the lower electrode 32, a resistance value of the lower electrode 32 may increase. On the other hand, when the nitrogen concentration on the capacitor electrode 24 side is lower than the nitrogen concentration on the oxide semiconductor layer 70 side, the total amount of nitrogen in the lower electrode 32 can be reduced as compared to when nitrogen is substantially uniformly distributed in the entire lower electrode 32. As a result, the resistance of the entire lower electrode 32 can be reduced.

In addition, in the lower electrode 32, the concentration of nitrogen at the position P2 is high. Therefore, most of oxygen atoms in the vicinity of the interface 501 can be substituted with nitrogen atoms. That is, the oxygen concentration in the vicinity of the interface 501 in the lower electrode 32 can be reduced. As a result, a difference between the oxygen concentration in the oxide semiconductor layer 70 and the oxygen concentration in the lower electrode 32 can be reduced, and a contact resistance between the oxide semiconductor layer 70 and the lower electrode 32 can be reduced.

In the metal oxide film 50a, a concentration of the second addition element at a position closer to the oxide semiconductor layer 70 may be higher than a concentration of the second addition element at a position farther from the oxide semiconductor layer 70. With this distribution of the second addition element, the same effect as that obtained from the distribution of the first addition element in the lower electrode 32 can be obtained.

### [Concentration Distribution 2 of First Addition Element in Lower Electrode 32]

FIG. 23 is a diagram illustrating an example of a concentration distribution of oxygen in the lower electrode of the present embodiment. As illustrated in FIG. 22, a concentration of the first addition element at a position P1 in the lower electrode 32 is higher than a concentration of the first addition element at a position P2 closer to the oxide semiconductor layer 70 than the position P1. In the present embodiment, a concentration of nitrogen at the position P1 is higher than a concentration of nitrogen at the position P2.

When the nitrogen concentration on the capacitor electrode 24 side is higher than the nitrogen concentration on the oxide semiconductor layer 70 side, the total amount of nitrogen in the lower electrode 32 can be reduced as compared to when nitrogen is substantially uniformly distributed in the entire lower electrode 32. As a result, the resistance of the entire lower electrode 32 can be reduced.

In addition, in the lower electrode 32, the nitrogen concentration at the position P2 is low. Therefore, the oxygen concentration at the position P2 can be increased as compared to the oxygen concentration at the position P1 and the oxygen concentration in the oxide semiconductor layer 70. As a result, an electrical field E1 substantially parallel to a direction from the position P1 toward the position P2 and an electrical field E2 substantially parallel to a direction from the oxide semiconductor layer 70 toward the position P2 are generated. The electrical field E2 corresponds to the electrical field E2 illustrated in FIG. 19. The electrical field E2 can be canceled out with the electrical field E1. Therefore, the size of the electrical field E2 can be reduced, and a contact resistance between the oxide semiconductor layer 70 and the lower electrode 32 can be reduced.

In the metal oxide film 50a, a concentration of the second addition element at a position close to the oxide semiconductor layer 70 may be lower than a concentration of the second addition element at a position far from the oxide semiconductor layer 70. With this distribution of the second addition element, the same effect as that obtained from the distribution of the first addition element in the lower electrode 32 can be obtained.

### First Modification Example

In the method of manufacturing the semiconductor device 30 illustrated in FIGS. 3 to 17, the metal oxide film 50a is formed outside of the transistor hole TH. However, the embodiment is not limited thereto, and the metal oxide film 50a may be formed in the transistor hole TH.

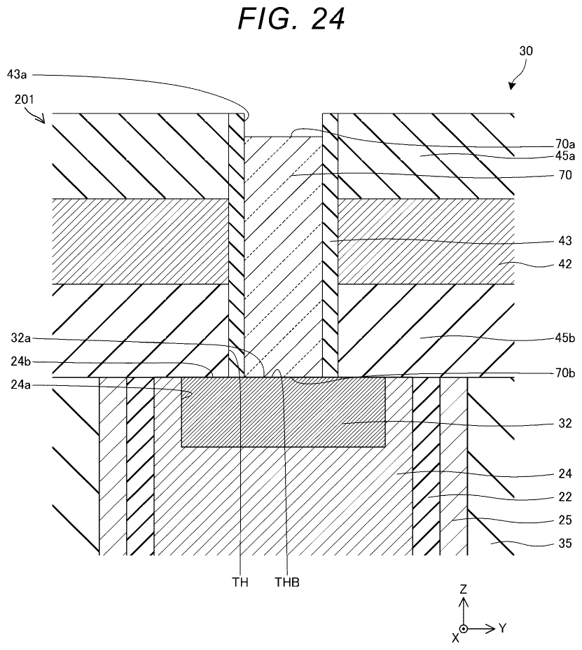

As illustrated in FIG. 24, by etching back the oxide semiconductor layer 70, a part of an upper region of the oxide semiconductor layer 70 is removed, and an upper side surface of the insulating film 45a is exposed. At this time, for example, the upper end 70a of the oxide semiconductor layer 70 is positioned in the transistor hole TH and is positioned above the conductive layer 42. A recess portion 43a, where the upper end 70a of the oxide semiconductor layer 70 is a bottom surface thereof and the gate insulating film 43 is a side surface thereof, is formed. At this time, a part of the gate insulating film 43 or the insulating film 45a may be etched. That is, the position of the gate insulating film 43 in the Z direction may be different from the position of the insulating film 45a in the Z direction.

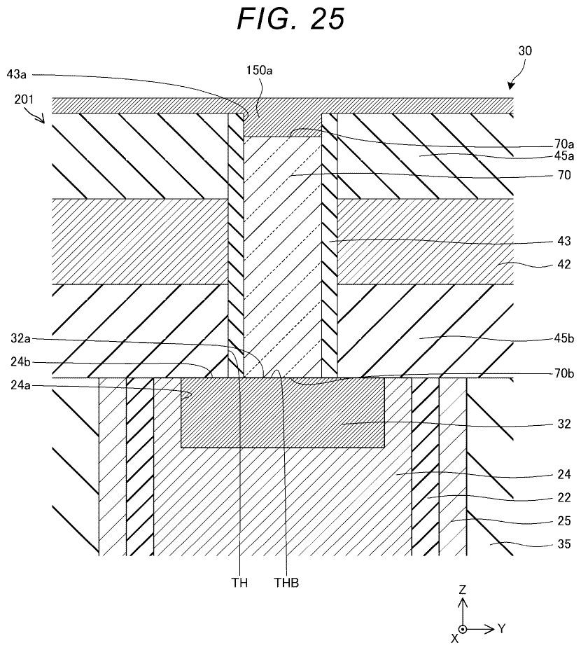

Next, as illustrated in FIG. 25, the second oxide conductive film 150a including the second addition element, indium, tin, and oxygen is formed on the recess portion 43a. In the present modification example, the second oxide conductive film 150a includes nitrogen, indium, tin, and oxygen.

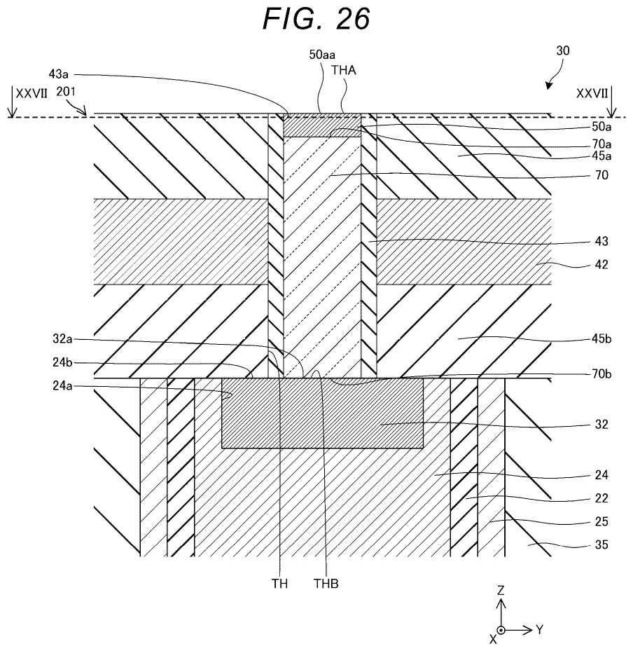

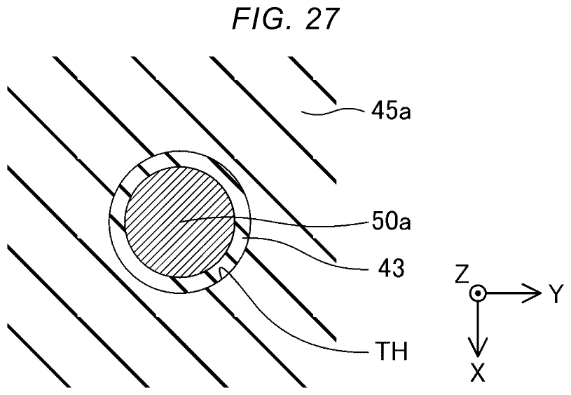

Next, as illustrated in FIGS. 26 and 27, a part of the second oxide conductive film 150a is removed. The position of the upper surface of the insulating film 45a in the Z direction and a position of a surface (hereinafter, also referred to as an upper surface 50aa) of the second oxide conductive film 150a in the Z direction are aligned, and the upper surface 50aa is exposed from an opening THA of the transistor hole TH. The second oxide conductive film 150a embedded in the recess portion 43a is the metal oxide film 50a. In a cross-section (an example of “first cross-section”) substantially parallel to the XY plane, the gate insulating film 43 surrounds the entirety of the metal oxide film 50a (refer to FIG. 27). Alternatively, in the cross-section, the gate insulating film 43 may be configured to surround a part of the metal oxide film 50a.

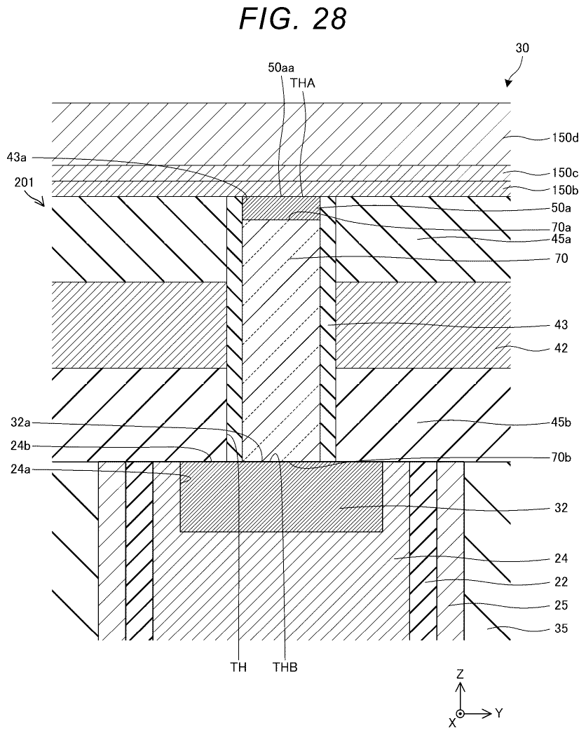

Next, as illustrated in FIG. 28, the barrier metal film 150b and the metal films 150c and 150d are formed on the metal oxide film 50a and the insulating film 45a from the lower side toward the upper side. The barrier metal film 150b and the metal films 150c and 150d extend substantially parallel to the XY plane.

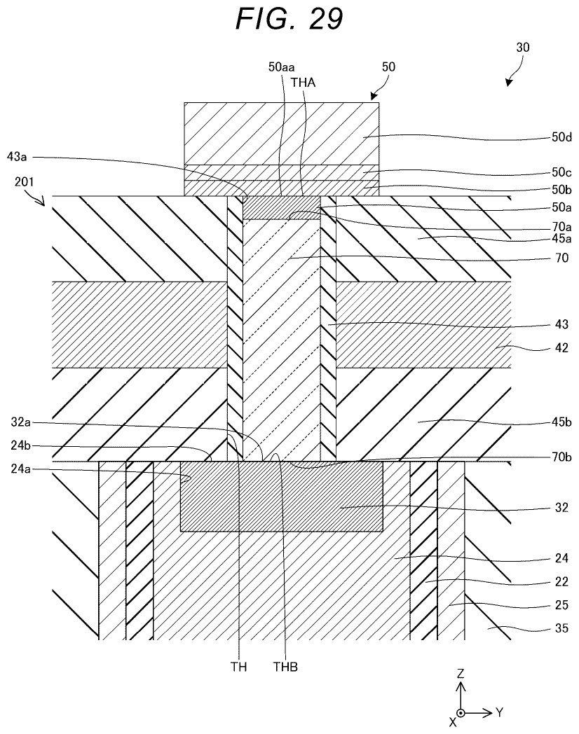

Next, as illustrated in FIG. 29, the upper electrode 50 is formed by etching the metal film 150d, the metal film 150c, and the barrier metal film 150b. The upper electrode 50 functions as a landing pad. The upper electrode 50 includes the metal oxide film 50a, the barrier metal layer 50b, the metal film 50c, and the metal film 50d.

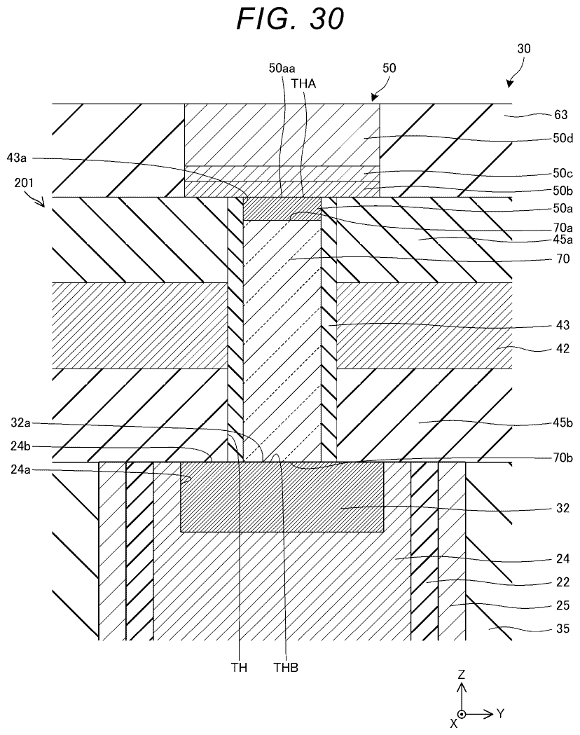

Next, as illustrated in FIG. 30, the insulating layer 63 covers the upper electrode 50. The upper surface of the insulating layer 63 is polished by chemical mechanical polishing.

The embodiment is not limited to the configuration where the entire metal oxide film 50a is embedded in the transistor hole TH, and a part of the metal oxide film 50a may be embedded in the transistor hole TH. In addition, the insulating layer 63 may be formed after forming the LP liner film 50e (refer to FIG. 17).

### Second Modification Example

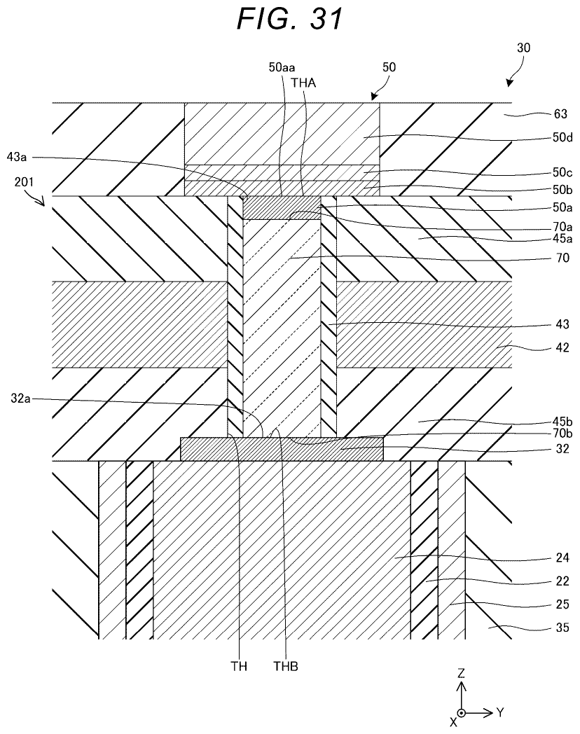

In the semiconductor device 30 illustrated in FIG. 30, the configuration where the lower electrode 32 is embedded in the recess portion 24a of the capacitor electrode 24 is described. However, the present disclosure is not limited to this configuration. As illustrated in FIG. 31, the lower electrode 32 may be configured to be provided above the capacitor electrode 24 without being embedded in the capacitor electrode 24.

In this case, as illustrated in FIG. 32, the first oxide conductive film 132 is formed above the capacitor electrode 24. The first oxide conductive film 132 extends substantially parallel to the XY plane.

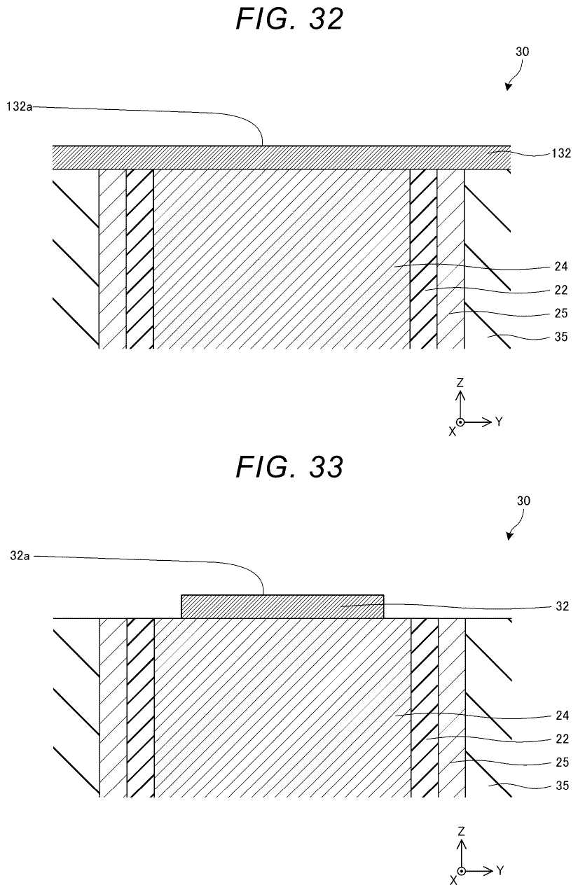

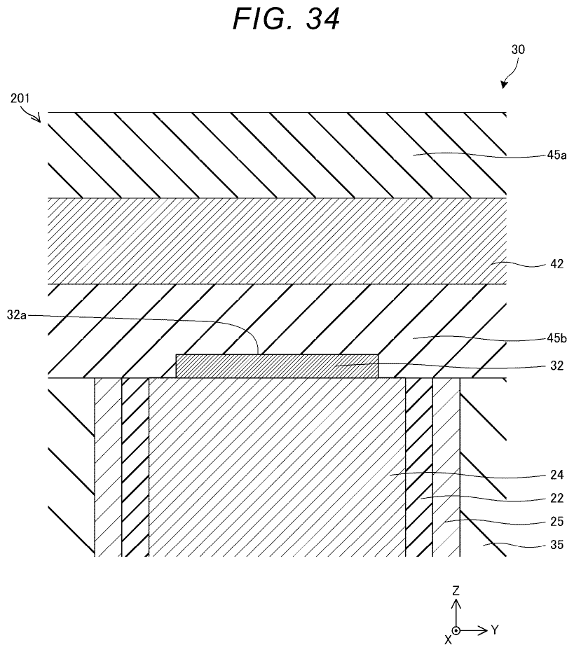

Next, as illustrated in FIG. 33, the lower electrode 32 that is provided above the capacitor electrode 24 without being embedded in the capacitor electrode 24 is formed from the first oxide conductive film 132. A width of the lower electrode 32 in the Y-axis direction does not need to be configured to be less than a width of the capacitor electrode 24 in the Y-axis direction and may be the same as or more than the width of the capacitor electrode 24 in the Y-axis direction.

Next, as illustrated in FIG. 34, the structure 201 is formed on the lower electrode 32.

[Concentration 1 of Nitrogen in Lower Electrode 32 and Metal Oxide Film 50a]

The concentration of the first addition element in the lower electrode 32 is higher than the concentration of the second addition element in the metal oxide film 50a. In the present embodiment, the concentration of nitrogen in the lower electrode 32 is higher than the concentration of nitrogen in the metal oxide film 50a.

For example, as illustrated in FIG. 12, when the oxide semiconductor layer 70 is formed in the transistor hole TH, oxygen is supplied to the lower electrode 32. On the other hand, due to the formation of the oxide semiconductor layer 70, oxygen is not supplied to the metal oxide film 50a. Therefore, the concentration of oxygen in the lower electrode 32 may be higher than the concentration of oxygen in the metal oxide film 50a. Even when the lower electrode 32 is formed of ITO without including nitrogen, oxygen defects in ITO decrease. Therefore, a resistance value of the lower electrode 32 increases. In addition, the electrical field E2 (refer to FIG. 19) generated by the dipole due to the increase in the oxygen concentration in the lower electrode 32 increases. Therefore, a contact resistance between the oxide semiconductor layer 70 and the lower electrode 32 increases.

Meanwhile, in the configuration where the concentration of nitrogen in the lower electrode 32 is higher than the concentration of nitrogen in the metal oxide film 50a, oxygen defects in the lower electrode 32 where the concentration of oxygen is high can be efficiently terminated with nitrogen to improve oxidative resistance.

[Concentration 2 of Nitrogen in Lower Electrode 32 and Metal Oxide Film 50a]

The concentration of the first addition element in the lower electrode 32 is lower than the concentration of the second addition element in the metal oxide film 50a. In the present embodiment, the concentration of nitrogen in the lower electrode 32 is lower than the concentration of nitrogen in the metal oxide film 50a.

For example, as illustrated in FIG. 15, in a step after forming the second oxide conductive film 150a, annealing may be performed in an oxygen atmosphere. In this annealing, a large amount of oxygen is supplied to the second oxide conductive film 150a as compared to the lower electrode 32.

When the metal oxide film 50a formed from the second oxide conductive film 150a is formed of ITO without including nitrogen, oxygen defects in ITO decrease. Therefore, a resistance value of the metal oxide film 50a increases. In addition, the electrical field E2 (refer to FIG. 19) generated by the dipole due to the increase in the oxygen concentration in the metal oxide film 50a increases. Therefore, a contact resistance between the oxide semiconductor layer 70 and the metal oxide film 50a increases.

Meanwhile, in the configuration where the concentration of nitrogen in the metal oxide film 50a is higher than the concentration of nitrogen in the lower electrode 32, oxygen defects in the metal oxide film 50a where the concentration of oxygen is high can be efficiently terminated with nitrogen to improve oxidative resistance.

[Concentration 3 of Nitrogen in Lower Electrode 32 and Metal Oxide Film 50a]

In addition, as illustrated in FIG. 3, the concentration of nitrogen in the lower electrode 32 that is embedded in the recess portion 24a is higher than the concentration of nitrogen in the metal oxide film 50a that is not embedded in the recess portion. In addition, as illustrated in FIG. 31, the concentration of nitrogen in the metal oxide film 50a that is embedded in the recess portion 43a is higher than the concentration of nitrogen in the lower electrode 32 that is not embedded in the recess portion.

The lower electrode 32 or the metal oxide film 50a includes nitrogen at a concentration that can improve the embeddability in the recess portion 24a or the recess portion.

In the present embodiment, the configuration where the oxide semiconductor layer 70 is IGZO is described. However, the present embodiment is not limited to this configuration. The oxide semiconductor layer 70 may be configured to be an oxide semiconductor layer having a different composition from IGZO.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A semiconductor device comprising:
a first conductor layer;
a second conductor layer;
an oxide semiconductor layer provided between the first conductor layer and the second conductor layer;
a gate electrode provided next to the oxide semiconductor layer; and
a gate insulating film provided between the gate electrode and the oxide semiconductor layer, wherein
the oxide semiconductor layer includes at least one of indium, gallium, zinc, aluminum, tin, titanium, silicon, germanium, copper, arsenic, and tungsten and oxygen and includes a first end and a second end,
the first conductor layer includes indium, tin, oxygen, and a first element that is at least one of nitrogen, sulfur, selenium, tellurium, hafnium, tantalum, tungsten, rhenium, osmium, iridium, bismuth, lanthanum, yttrium, zinc, cadmium, and mercury, and
the first end of the oxide semiconductor layer is in contact with the first conductor layer.

2. The semiconductor device according to claim 1, wherein the semiconductor device further includes:
a first capacitor electrode that surrounds the first conductor layer and is in contact with the first conductor layer in a first cross-section perpendicular to a first direction that extends from the first conductor layer toward the second conductor layer,
a dielectric film that surrounds the first capacitor electrode and is in contact with the first capacitor electrode in the first cross-section, and
a second capacitor electrode that surrounds the dielectric film and is in contact with the dielectric film in the first cross-section.

3. The semiconductor device according to claim 1, wherein a concentration of the first element in the first conductor layer is 3% or higher.

4. The semiconductor device according to claim 1, wherein
the second conductor layer includes indium, tin, oxygen, and a second element that is at least one of nitrogen, sulfur, selenium, tellurium, hafnium, tantalum, tungsten, rhenium, osmium, iridium, bismuth, lanthanum, yttrium, zinc, cadmium, and mercury,
the second end of the oxide semiconductor layer is in contact with the second conductor layer, and
a concentration of the first element in the first conductor layer is higher than a concentration of the second element in the second conductor layer.

5. The semiconductor device according to claim 1, wherein
the second conductor layer includes indium, tin, oxygen, and a second element that is at least one of nitrogen, sulfur, selenium, tellurium, hafnium, tantalum, tungsten, rhenium, osmium, iridium, bismuth, lanthanum, yttrium, zinc, cadmium, and mercury,
the second end of the oxide semiconductor layer is in contact with the second conductor layer, and
a concentration of the first element in the first conductor layer is lower than a concentration of the second element in the second conductor layer.

6. The semiconductor device according to claim 5, wherein the gate insulating film surrounds at least a part of the second conductor layer in a first cross-section perpendicular to a first direction from the first conductor layer toward the second conductor layer.

7. The semiconductor device according to claim 1, wherein a concentration of the first element at a first position in the first conductor layer is lower than a concentration of the first element at a second position closer to the oxide semiconductor layer than the first position.

8. The semiconductor device according to claim 1, wherein a concentration of the first element at a first position in the first conductor layer is higher than a concentration of the first element at a second position closer to the oxide semiconductor layer than the first position.

9. A semiconductor memory device comprising:
the semiconductor device according to claim 1; and
a capacitor electrically connected to the first conductor layer,
wherein the capacitor includes a first capacitor electrode, a second capacitor electrode, and a dielectric film provided between the first capacitor electrode and the second capacitor electrode.

10. The semiconductor device according to claim 9, wherein
the first conductor layer is in contact with the first capacitor electrode and not surrounded by the first capacitor electrode, and
the first capacitor electrode extends in the first direction and is surrounded by the second capacitor electrode.

11. A method of manufacturing a semiconductor device, the method comprising:
forming an oxide conductive film on a substrate, the oxide conductive film including indium, tin, oxygen, and at least one of nitrogen, sulfur, selenium, tellurium, hafnium, tantalum, tungsten, rhenium, osmium, iridium, bismuth, lanthanum, yttrium, zinc, cadmium, and mercury;
forming a structure that includes a first insulating film, a second conductive film, and a second insulating film stacked on the oxide conductive film;
forming a hole portion in the structure such that a surface of the oxide conductive film formed on the substrate is exposed;
forming a third insulating film to cover the inside of the hole portion;
removing the third insulating film formed on the oxide conductive film; and
forming an oxide semiconductor film in the hole portion such that the oxide semiconductor film is in contact with the oxide conductive film.

12. The method of manufacturing a semiconductor device according to claim 11, wherein
the oxide conductive film is formed by depositing an oxide conductor including indium, tin, and oxygen with a sputtering method in a state where gas including at least one of nitrogen, sulfur, selenium, tellurium, hafnium, tantalum, tungsten, rhenium, osmium, iridium, bismuth, lanthanum, yttrium, zinc, cadmium, and mercury is introduced.

13. The method of manufacturing a semiconductor device according to claim 11, wherein
the oxide conductive film is formed with a sputtering method using a target including at least one of nitrogen, sulfur, selenium, tellurium, hafnium, tantalum, tungsten, rhenium, osmium, iridium, bismuth, lanthanum, yttrium, zinc, cadmium, and mercury and a target including indium, tin, and oxygen.

14. The method of manufacturing a semiconductor device according to claim 11, wherein
the oxide conductive film is formed with a sputtering method using a target including indium, tin, oxygen, and at least one of nitrogen, sulfur, selenium, tellurium, hafnium, tantalum, tungsten, rhenium, osmium, iridium, bismuth, lanthanum, yttrium, zinc, cadmium, and mercury.

15. The method of manufacturing a semiconductor device according to claim 11, wherein
the oxide conductive film is formed by forming a first film including indium, tin, and oxygen on the substrate and exposing the first film to gas including at least one of nitrogen, sulfur, selenium, tellurium, hafnium, tantalum, tungsten, rhenium, osmium, iridium, bismuth, lanthanum, yttrium, zinc, cadmium, and mercury.

16. The method of manufacturing a semiconductor device according to claim 11, wherein
the oxide conductive film is formed by forming a first film including indium, tin, and oxygen on the substrate and causing at least one of nitrogen, sulfur, selenium, tellurium, hafnium, tantalum, tungsten, rhenium, osmium, iridium, bismuth, lanthanum, yttrium, zinc, cadmium, and mercury that is ionized to collide with the first film using an electrical field.

17. A semiconductor memory device comprising:
a first conductor layer;
a second conductor layer;
an oxide semiconductor layer extending in a first direction between the first conductor layer and the second conductor layer;
a gate electrode provided next to the oxide semiconductor layer;
a gate insulating film provided between the gate electrode and the oxide semiconductor layer;
a first capacitor electrode extending the first direction and in contact with the first conductor layer;
a second capacitor electrode extending in the first direction and surrounding the first capacitor electrode; and
a dielectric film between and in contact with the first capacitor electrode and the second capacitor electrode, wherein
the oxide semiconductor layer includes at least one of indium, gallium, zinc, aluminum, tin, titanium, silicon, germanium, copper, arsenic, and tungsten and oxygen and includes a first end and a second end,
the first conductor layer includes indium, tin, oxygen, and a first element that is at least one of nitrogen, sulfur, selenium, tellurium, hafnium, tantalum, tungsten, rhenium, osmium, iridium, bismuth, lanthanum, yttrium, zinc, cadmium, and mercury, and
the first end of the oxide semiconductor layer is in contact with the first conductor layer.

18. The semiconductor memory device according to claim 17, wherein the second conductor layer is partially embedded in the oxide semiconductor layer.

19. The semiconductor memory device according to claim 18, wherein the second conductor layer includes a first part that is embedded in the oxide semiconductor layer and second part that is wider than the first part and not embedded in the oxide semiconductor layer.

20. The semiconductor memory device according to claim 17, wherein the first conductor layer is embedded in the first capacitor electrode.
